(19) United States
(12) Patent Application Publication
(10) Pub. No.: US 2024/0412779 A1
(43) Pub. Date: Dec. 12, 2024

(54) PRE-CHARGE SYSTEM FOR PERFORMING TIME-DIVISION PRE-CHARGE UPON BIT-LINE GROUPS OF MEMORY ARRAY AND ASSOCIATED PRE-CHARGE METHOD

(71) Applicant: MEDIATEK INC., Hsin-Chu (TW)

(72) Inventors: Yi-Te Chiu, Hsinchu City (TW); Ya-Ting Yang, Hsinchu City (TW); Jia-Jing Chen, Hsinchu City (TW)

(73) Assignee: MEDIATEK INC., Hsin-Chu (TW)

(21) Appl. No.: 18/739,363

(22) Filed: Jun. 11, 2024

Related U.S. Application Data
(60) Provisional application No. 63/472,354, filed on Jun. 12, 2023.

(51) Int. Cl. G11C 11/418; G11C 5/06

(52) U.S. Cl. CPC G11C 11/418; G11C 5/063; G11C 2207/22

(57) ABSTRACT

A pre-charge system includes a pre-charge circuit and a timing controller circuit. The pre-charge circuit performs time-division pre-charge upon a plurality of bit-line groups of a memory array according to a plurality of pre-charge timing control signals, wherein the memory array includes a plurality of memory cells each coupled to one of the plurality of bit-line groups. The timing controller circuit generates and outputs the plurality of pre-charge timing control signals to the pre-charge circuit.

### CROSS REFERENCE TO RELATED APPLICATIONS

This application claims the benefit of U.S. Provisional Application No. 63/472, 354, filed on Jun. 12, 2023. The content of the application is incorporated herein by reference.

### BACKGROUND

The present invention relates to a memory design, and more particularly, to a pre-charge system for performing time-division pre-charge upon bit-line groups (e.g., complementary bit-line pairs) of a memory array and an associated pre-charge method.

During technology shrinkage, area and capacitance shrink, while metal resistance and current density become increased. However, increasing resistance and decreasing width of metal wires introduce many electro-migration and IR drop issues in a system-on-chip (SoC). Reducing/limiting the peak current is the most efficient way to address electro-migration and IR drop issues.

Static random-access memory (SRAM) is a type of semiconductor memory that consists of a bi-stable unit cell storing 1 or 0 as a single bit. Bit-lines have large capacitance due to their lengths. In a conventional SRAM system, bit-lines are pre-charged to a reference voltage (e.g., VDD) for faster read and write operations. However, the conventional SRAM system may consume a huge amount of energy and introduce a large peak current during the pre-charge phase, and may be subject to the electro-migration and IR drop issues.

### SUMMARY

One of the objectives of the claimed invention is to provide a pre-charge system for performing time-division pre-charge upon bit-line groups (e.g., complementary bit-line pairs) of a memory array and an associated pre-charge method.

According to a first aspect of the present invention, an exemplary pre-charge system is disclosed. The exemplary pre-charge system includes a pre-charge circuit and a timing controller circuit. The pre-charge circuit is arranged to perform time-division pre-charge upon a plurality of bit-line groups of a memory array according to a plurality of pre-charge timing control signals, wherein the memory array comprises a plurality of memory cells each coupled to one of the plurality of bit-line groups. The timing controller circuit is arranged to generate and output the plurality of pre-charge timing control signals to the pre-charge circuit.

According to a second aspect of the present invention, an exemplary pre-charge method is disclosed. The exemplary pre-charge method includes: generating a plurality of pre-charge timing control signals; and performing time-division pre-charge upon a plurality of bit-line groups of a memory array according to the plurality of pre-charge timing control signals, wherein the memory array comprises a plurality of memory cells each coupled to one of the plurality of bit-line groups.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a memory according to an embodiment of the present invention.

FIG. 2 is a diagram illustrating a non-time-division pre-charge scheme.

FIG. 3 is a diagram illustrating waveforms of a plurality of signals of a memory using the non-time-division pre-charge scheme.

FIG. 4 is a diagram illustrating a first approach that employs time-division pre-charge according to an embodiment of the present invention.

FIG. 5 is a diagram illustrating waveforms of a plurality of signals of a memory using the first approach according to an embodiment of the present invention.

FIG. 6 is a diagram illustrating a second approach that employs time-division pre-charge according to an embodiment of the present invention.

FIG. 7 is a diagram illustrating waveforms of a plurality of signals of a memory using the second approach according to an embodiment of the present invention.

FIG. 8 is a diagram illustrating a third approach that employs time-division pre-charge according to an embodiment of the present invention.

FIG. 9 is a diagram illustrating waveforms of a plurality of signals of a memory using the third approach according to an embodiment of the present invention.

FIG. 10 is a diagram illustrating a pre-charge timing generator circuit according to an embodiment of the present invention.

FIG. 11 is a diagram illustrating waveforms of a plurality of signals of a memory using the pre-charge timing generator circuit 1000 with a first adjustable delay setting.

FIG. 12 is a diagram illustrating waveforms of a plurality of signals of a memory using the pre-charge timing generator circuit 1000 with a second adjustable delay setting.

FIG. 13 is a diagram illustrating another pre-charge timing generator circuit according to an embodiment of the present invention.

FIG. 14 is a diagram illustrating implementation of tracking circuits of the pre-charge timing generator circuit shown in FIG. 13 according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

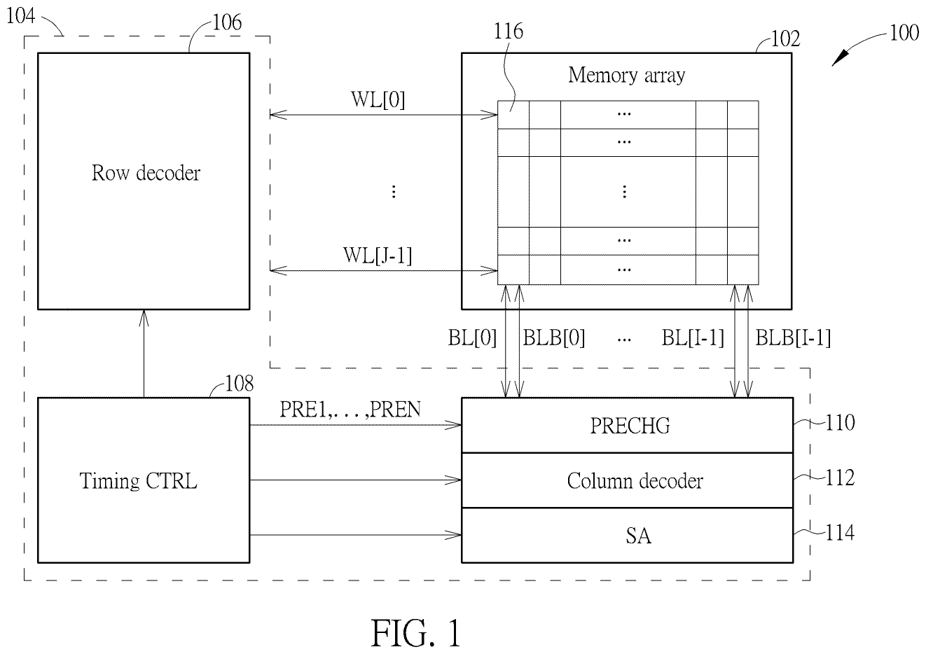

FIG. 1 is a diagram illustrating a memory according to an embodiment of the present invention. By way of example, but not limitation, the memory 100 may be an SRAM memory that supports the proposed time-division pre-charge scheme. In practice, any memory using the proposed time-division pre-charge scheme falls within the scope of the present invention. The memory 100 includes a memory array 102 and a peripheral circuit 104. The peripheral circuit 104 is arranged to control access (read/write) of the memory array 102, and may include a row decoder circuit (labeled by “Row decoder”) 106, a timing controller circuit (labeled by “Time CTRL”) 108, a pre-charge circuit (labeled by “PRECHG”) 110, a column decoder circuit (labeled by “Column decoder”) 112, and a sense amplifier circuit (labeled by “SA”) 114. It should be noted that the architecture shown in FIG. 1 is for illustrative purposes only, and is not meant to be a limitation of the present invention. For example, the peripheral circuit 104 may include additional circuits (e.g., input/output buffers), depending upon actual design considerations.

The memory array 102 is a cell array including a plurality of memory cells 116 arranged in a two-dimensional array with a plurality of rows and a plurality of columns. For example, each of the memory cells 116 is an SRAM cell used for storing one bit, and the memory array 102 has an SRAM size of I×J, and includes a plurality of word-lines WL[0]-WL[J-1] along the column direction and a plurality of bit-line groups (e.g., complementary bit-line pairs (BL[0], BLB[0])-(BL[I-1], BLB[I-1])) along the row direction, where each of the bit-line groups (BL[0], BLB[0])-(BL[I-1], BLB[I-1]) corresponds to one memory cell column, and each of the word-lines WL[0]-WL[J-1] corresponds to one memory cell row. In this embodiment, each bit-line group is shown having a pair of bit-lines. However, this is for illustrative purposes only, and is not meant to be a limitation of the present invention. In practice, the proposed time-division pre-charge scheme may be applicable for any bit-line group size. That is, the number of bit-lines used by each memory cell depends on the memory cell architecture. The bit-line group of one memory cell may include two or more bit-lines, depending upon the actual memory cell design. For better comprehension of technical features of the present invention, the following assumes that each bit-line group is a complementary bit-line pair (BL, BLB).

In this embodiment, the pre-charge circuit 110 and the timing controller circuit 108 may be regarded as parts of a pre-charge system, where the timing controller circuit 108 includes a pre-charge timing controller circuit arranged to generate and output multiple pre-charge timing control signals PRE1-PREN (N≥2) to the pre-charge circuit 110, and the pre-charge circuit 110 is arranged to perform time-division pre-charge upon the bit-line groups (BL[0], BLB[0])-(BL[I-1], BLB[I-1]) of the memory array 102 according to the pre-charge timing control signals PRE1-PREN (N≥2) generated from the timing controller circuit 108. It should be noted that the timing controller circuit 108 also controls timing of other circuits, including row decoder circuit 106, column decoder circuit 112, sense amplifier 114, etc. Since the present invention is focused on the proposed time-division pre-charge scheme and a person skilled in the art should readily understand principles of memory array 102, row decoder circuit 106, column decoder circuit 112, and sense amplifier 114, further description of memory array 102, row decoder circuit 106, column decoder circuit 112, and sense amplifier 114 is omitted here for brevity.

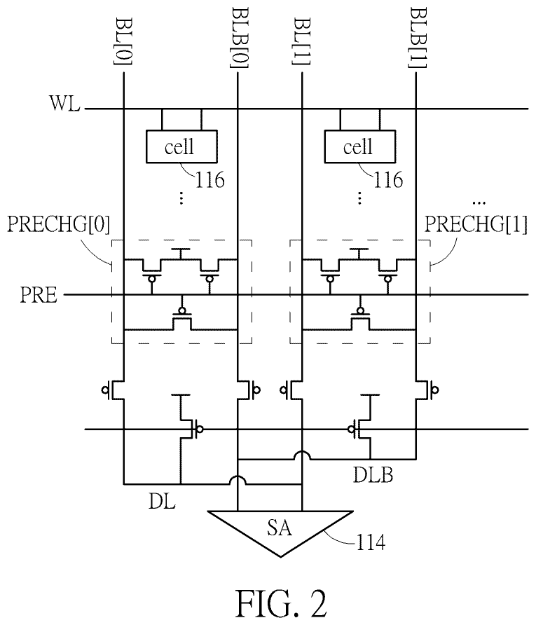

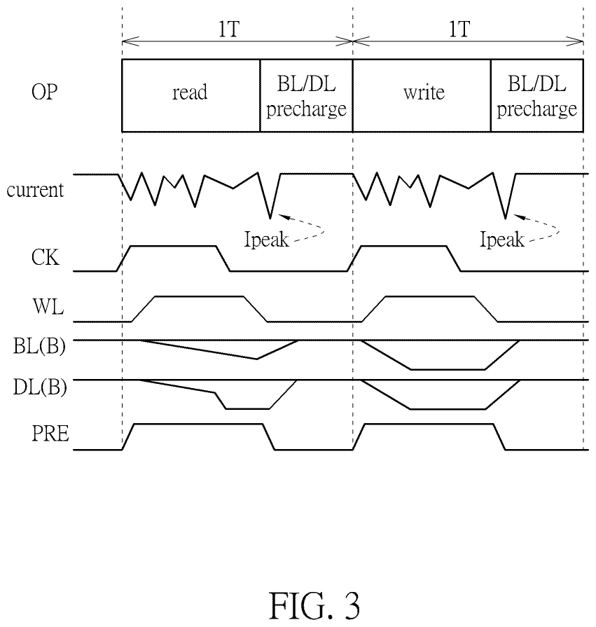

The conventional SRAM system may consume a huge amount of energy and introduce a large peak current during the pre-charge phase, and may be subject to the electro-migration and IR drop issues. To address these issues, the present invention proposes the time-division pre-charge scheme to achieve spike current restriction. Please refer to FIG. 2 in conjunction with FIG. 3. FIG. 2 is a diagram illustrating a non-time-division pre-charge scheme. FIG. 3 is a diagram illustrating waveforms of a plurality of signals of a memory using the non-time-division pre-charge scheme. After an SRAM read/write operation, bit-lines (e.g., BL[0], BLB[0], BL[1], and BLB[1] shown in FIG. 2) and data-lines (e.g., DL and DLB shown in FIG. 2) are pre-charged to an initial voltage level (e.g., VDD). In accordance with the non-time-division r pre-charge scheme, a pre-charge circuit includes a plurality of pre-charge sub-circuits (e.g., PRECHG[0] and PRECHG[1] shown in FIG. 2) coupled to a plurality of bit-line groups (e.g., (BL[0], BLB[0]) and (BL[1], BLB[1])), respectively, and all of the pre-charge sub-circuits (e.g., PRECHG[0] and PRECHG[1]) are simultaneously enabled by a single pre-charge timing control signal PRE. As shown in FIG. 3, pre-charging bit-lines and data-lines at the same time consumes a huge amount of energy and introduces a large peak current Ipeak. To reduce the peak current Ipeak introduced by the pre-charge process, the present invention proposes several approaches that are based on the time-division pre-charge scheme. Further details of the proposed time-division pre-charge scheme are described as below with reference to the accompanying drawings.

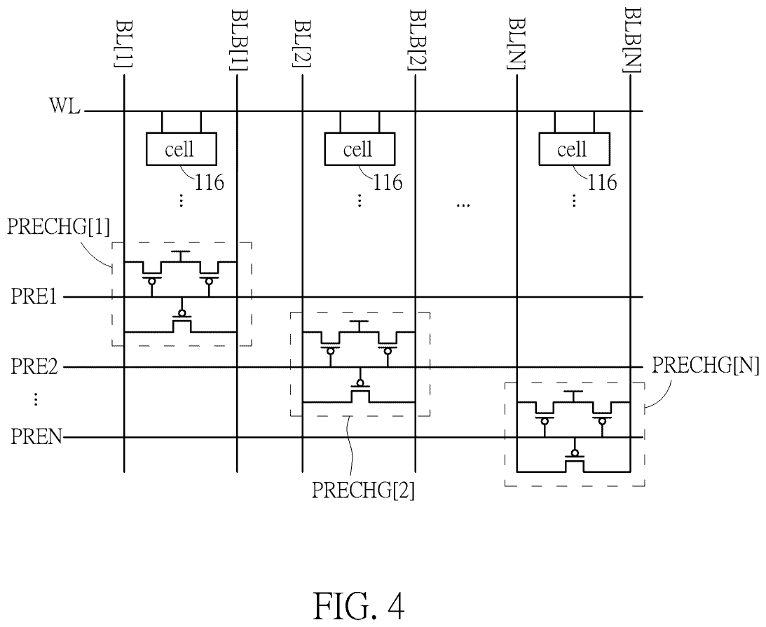

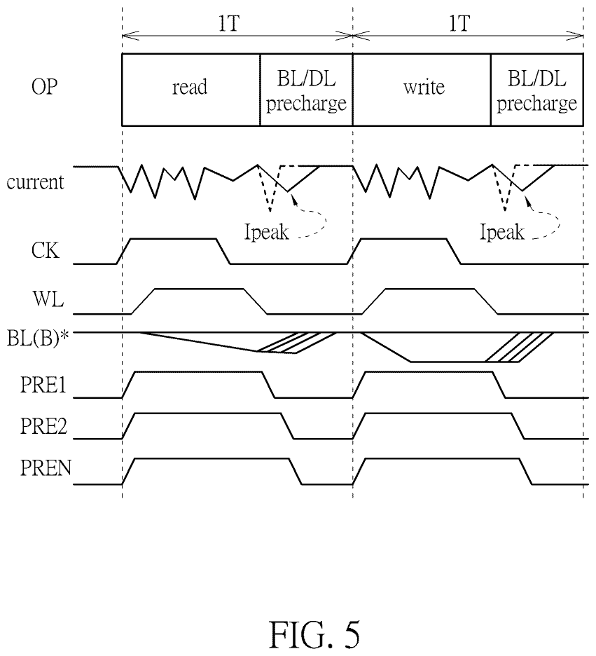

Please refer to FIG. 4 in conjunction with FIG. 5. FIG. 4 is a diagram illustrating a first approach that employs time-division pre-charge according to an embodiment of the present invention. FIG. 5 is a diagram illustrating waveforms of a plurality of signals of the memory 100 using the first approach according to an embodiment of the present invention. The bit-line groups (BL[0], BLB[0])-(BL[I-1], BLB[I-1]) of the memory array 102 are categorized into N bit-line pre-charge groups, where each bit-line pre-charge group may include one or more bit-line groups, depending upon actual design considerations. Hence, the pre-charge circuit 110 is configured to have N pre-charge sub-circuit groups, each having one or more pre-charge sub-circuits and receiving one of the pre-charge timing control signals PRE1-PREN generated from the timing controller circuit 108. In accordance with the first approach, the pre-charge timing control signals PRE1-PREN generated from the timing controller circuit 108 enable N pre-charge sub-circuit groups sequentially. For better comprehension of technical features of the first approach, the following assumes that each bit-line pre-charge group includes only a single bit-line group, and each pre-charge sub-circuit group includes only a single pre-charge sub-circuit.

As shown in FIG. 4, a 1^{st} pre-charge sub-circuit group includes a pre-charge sub-circuit PRECHG[1] that is implemented using three P-type Metal-Oxide-Semiconductor (PMOS) transistors and is coupled to a bit-line group (BL[1], BLB[1]), and is enabled/disabled by a pre-charge timing control signal PRE1; a 2^{nd} pre-charge sub-circuit group includes a pre-charge sub-circuit PRECHG[2] that is implemented using three PMOS transistors and is coupled to a bit-line group (BL[2], BLB[2]), and is enabled/disabled by a pre-charge timing control signal PRE2; and an N^{th} pre-charge sub-circuit group includes a pre-charge sub-circuit PRECHG[N] that is implemented using three PMOS transistors and is coupled to a bit-line group (BL[N], BLB[N]), and is enabled/disabled by a pre-charge timing control signal PREN. The pre-charge timing control signals PRE1-PREN are properly set by the timing controller circuit 108 to sequentially enable the pre-charge sub-circuits PRECHG[1]-PRECHG[N]. For example, timing of 1→0 transition of a pre-charge timing control signal PRE[i+1] is later than timing of 1→0 transition of a pre-charge timing control signal PRE[i], where 1≤i≤N−1. As shown in FIG. 5, the timing of 1→0 transition of the pre-charge timing control signal PRE2 is later than the timing of 1→0 transition of the pre-charge timing control signal PRE1. Similarly, the timing of 1→0 transition of the pre-charge timing control signal PRE3 (not shown) is later than the timing of 1→0 transition of the pre-charge timing control signal PRE2, and the timing of 1→0 transition of the pre-charge timing control signal PREN is later than the timing of 1→0 transition of the pre-charge timing control signal PRE(N-1) (not shown). Since all of the pre-charge sub-circuits PRECHG[1]-PRECHG[N] are not simultaneously enabled, the peak current Ipeak introduced during the pre-charge process can be reduced.

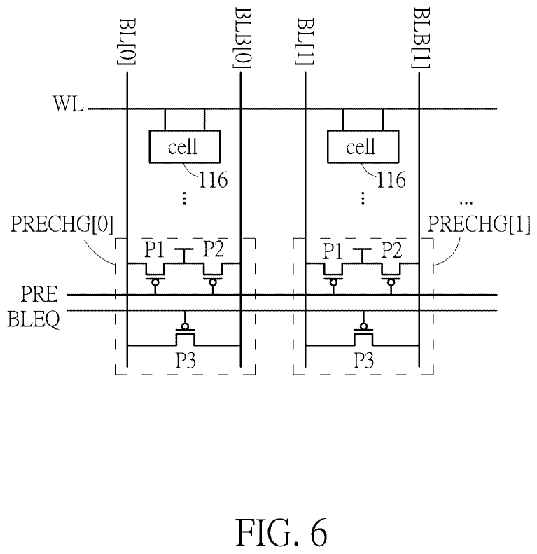

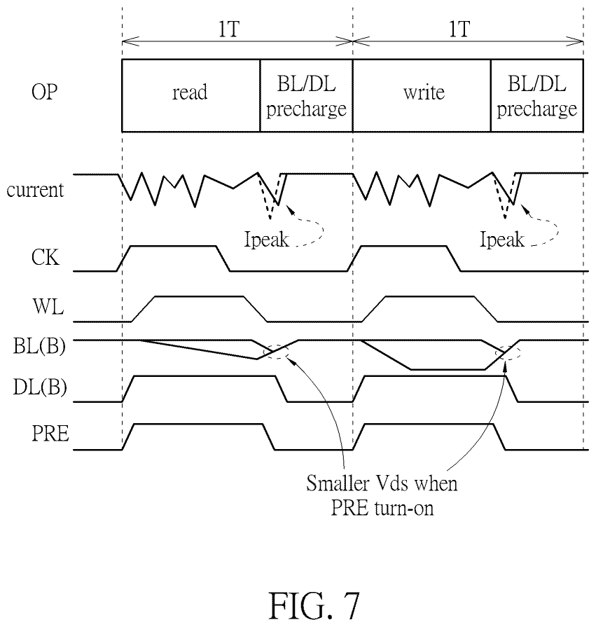

Please refer to FIG. 6 in conjunction with FIG. 7. FIG. 6 is a diagram illustrating a second approach that employs time-division pre-charge according to an embodiment of the present invention. FIG. 7 is a diagram illustrating waveforms of a plurality of signals of the memory 100 using the second approach according to an embodiment of the present invention. Each pre-charge sub-circuit of the pre-charge circuit 110 is divided into two parts that are enabled in a sequential manner. Specifically, the pre-charge circuit 110 includes a plurality of pre-charge sub-circuits coupled to the bit-line groups (BL[0], BLB[0])-(BL[I-1], BLB[I-1]), respectively. Each of the pre-charge sub-circuits receives all of the pre-charge timing control signals PRE1-PREN (e.g., PRE and BLEQ in this embodiment) and is enabled/disabled by the pre-charge timing control signals PRE1-PREN (e.g., PRE and BLEQ in this embodiment). In addition, each of the pre-charge sub-circuits includes an equalizer and a pre-charge device. In accordance with the second approach, the pre-charge timing control signals PRE1-PREN (e.g., PRE and BLEQ in this embodiment) generated from the timing controller circuit 108 enable the equalizer and the pre-charge device of the same pre-charge sub-circuit sequentially.

As shown in FIG. 6, a pre-charge sub-circuit PRECHG[0] includes an equalizer (which is implemented by a PMOS transistor P3) and a pre-charge device (which is implemented by two PMOS transistors P1 and P2), and a pre-charge sub-circuit PRECHG[1] includes an equalizer (which is implemented by a PMOS transistor P3) and a pre-charge device (which is implemented by two PMOS transistors P1 and P2). The pre-charge sub-circuit PRECHG[0] is coupled to a bit-line group (BL[0], BLB[0]), and receives both of the pre-charge timing control signals PRE and BLEQ, where the equalizer (which is implemented by PMOS transistor P3) is enabled/disabled by the pre-charge timing control signal BLEQ, and the pre-charge device (which is implemented by PMOS transistors P1 and P2) is enabled/disabled by the pre-charge timing control signal PRE. The pre-charge sub-circuit PRECHG[1] is coupled to a bit-line group (BL[1], BLB[1]), and receives both of the pre-charge timing control signals PRE and BLEQ, where the equalizer (which is implemented by PMOS transistor P3) is enabled/disabled by the pre-charge timing control signal BLEQ, and the pre-charge device (which is implemented by PMOS transistors P1 and P2) is enabled/disabled by the pre-charge timing control signal PRE.

The pre-charge timing control signals PRE and BLEQ are properly set by the timing controller circuit 108 to sequentially enable the equalizer (which is implemented by PMOS transistor P3) and the pre-charge device (which is implemented by PMOS transistors P1 and P2) of each pre-charge sub-circuit PRECHG[0]/PRECHG[1]. For example, timing of 1→0 transition of the pre-charge timing control signal PRE is later than timing of 1→0 transition of a pre-charge timing control signal BLEQ. Hence, regarding the same pre-charge sub-circuit PRECHG[0] (or PRECHG[1]), the equalizer (which is implemented by PMOS transistor P3) is first enabled to initiate charge sharing between bit-lines BL[0] and BLB[0] (or BL[1] and BLB[1]) of a corresponding bit-line group. In this way, the drain-to-source voltage Vds of each of the PMOS transistors P1 and P2 can be reduced to a lower voltage value at the time the pre-charge device (which is implemented by PMOS transistors P1 and P2) is enabled. Since the whole pre-charge sub-circuits PRECHG[1]-PRECHG[N] are not simultaneously enabled, the peak current Ipeak introduced during the pre-charge process can be reduced. Specifically, with the help of early bit-line equalization, the subsequent pre-charge operation introduces a smaller peak current.

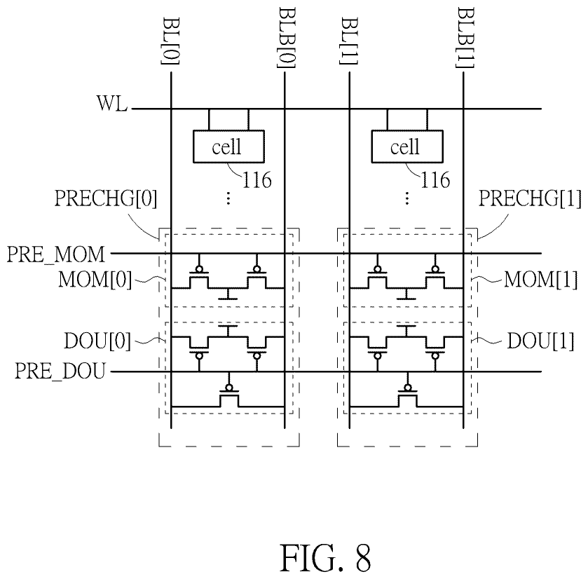

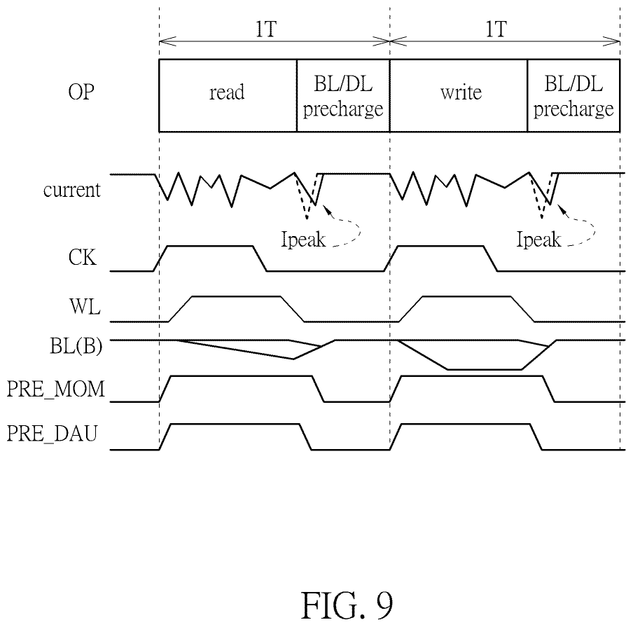

Please refer to FIG. 8 in conjunction with FIG. 9. FIG. 8 is a diagram illustrating a third approach that employs time-division pre-charge according to an embodiment of the present invention. FIG. 9 is a diagram illustrating waveforms of a plurality of signals of the memory 100 using the third approach according to an embodiment of the present invention. Each pre-charge sub-circuit of the pre-charge circuit 110 is configured to have an additional pre-charge device that is a smaller pre-charge device with weaker pre-charge strength and can act as a peak current limiter. The additional pre-charge device may be regarded as a daughter device. The daughter device (which is a smaller pre-charge device with weaker pre-charge strength) and a mother device (which is a larger pre-charge device with stronger pre-charge strength) of the same pre-charge sub-circuit are enabled in a sequential manner.

Specifically, the pre-charge circuit 110 includes a plurality of pre-charge sub-circuits coupled to the bit-line groups (BL[0], BLB[0])-(BL[I-1], BLB[I-1]), respectively. Each of the pre-charge sub-circuits receives all of the pre-charge timing control signals PRE1-PREN (e.g., PRE_MOM and PRE_DAU in this embodiment). In addition, each of the pre-charge sub-circuits includes a first pre-charge device (e.g., daughter device) and a second pre-charge device (e.g., mother device), where pre-charge strength of the second pre-charge device (e.g., mother device) is larger than pre-charge strength of the first pre-charge device (e.g., daughter device). In accordance with the third approach, the pre-charge timing control signals PRE1-PREN (e.g., PRE_MOM and PRE_DAU in this embodiment) generated from the timing controller circuit 108 enable the first pre-charge device (daughter device) and the second pre-charge device (mother device) of the same pre-charge sub-circuit sequentially.

As shown in FIG. 8, a pre-charge sub-circuit PRECHG[0] includes a mother device MOM[0] (which may be implemented by large-sized PMOS transistors) and a daughter device DAU[0] (which is may be implemented by small-sized PMOS transistors), and a pre-charge sub-circuit PRECHG[1] includes a mother device MOM[1] (which may be implemented by large-sized PMOS transistors) and a daughter device DAU[1] (which is may be implemented by small-sized PMOS transistors). In this embodiment, an equalizer is implemented in the daughter device DAU[0]/DAU[1]. However, this is for illustrative purposes only, and is not meant to be a limitation of the present invention. Since the equalizer is used for charge sharing between bit-lines of the same bit-line group, it has no impact on the peak current. In an alternative design, the equalizer may be omitted from the daughter device DAU[0]/DAU[1] and implemented in the mother device MOM[0]/MOM[1] instead.

The pre-charge sub-circuit PRECHG[0] is coupled to a bit-line group (BL[0], BLB[0]), and receives all of the pre-charge timing control signals PRE_MOM and PRE_DAU, where the mother device MOM[0] is enabled/disabled by the pre-charge timing control signal PRE_MOM, and the daughter device DAU[0] is enabled/disabled by the pre-charge timing control signal PRE_DAU. The pre-charge sub-circuit PRECHG[1] is coupled to a bit-line group (BL[1], BLB[1]), and receives all of the pre-charge timing control signals PRE_MOM and PRE_DAU, where the mother device MOM[1] is enabled/disabled by the pre-charge timing control signal PRE_MOM, and the daughter device DAU[1] is enabled/disabled by the pre-charge timing control signal PRE_DAU. The pre-charge timing control signals PRE1 and BLEQ are properly set by the timing controller circuit 108 to sequentially enable the daughter device (which may be implemented by small-sized PMOS transistors) DAU[0]/DAU[1] and the mother device (which may be implemented by large-sized PMOS transistors) MOM[0]/MOM[1] of each pre-charge sub-circuit PRECHG[0]/PRECHG[1]. As shown in FIG. 9, timing of 1→0 transition of the pre-charge timing control signal PRE_MOM is later than timing of 1→0 transition of the pre-charge timing control signal PRE_DAU. Hence, regarding the same pre-charge sub-circuit PRECHG[0] (or PRECHG[1]), the daughter device DAU[0] (or DAU[1]) is first enabled to initiate pre-charge of a corresponding bit-line group (BL[0], BLB[0]) (or (BL[1], BLB[1])). Since the daughter device DAU[0] (or DAU[1]) has weaker pre-charge strength compared to the mother device MOM[0]/MOM[1], the peak current is limited by the daughter device DAU[0] (or DAU[1]). After the corresponding bit-line group (BL[0], BLB[0]) (or (BL[1], BLB[1])) is pre-charged to a certain voltage level by the daughter device DAU[0] (or DAU[1]), the mother device MOM[0]/MOM[1] is enabled to make the corresponding bit-line group (BL[0], BLB[0]) achieve the target voltage level VDD. Since mother devices of all pre-charge sub-circuits PRECHG[1]-PRECHG[N] are not simultaneously enabled at the beginning of the pre-charge phase, the peak current Ipeak introduced during the pre-charge process can be reduced due to peak current limiting that is provided by daughter devices. In addition, the follow-up pre-charge provided by mother devices introduces a smaller peak current when driving bit-lines from an intermediate voltage level (which is pre-charged by daughter devices) to a target voltage level VDD.

The pre-charge timing control signals PRE1-PREN (e.g., PRE1-PREN of proposal 1, PRE and BLEQ of proposal 2, or PRE_MOM and PRE_DAU of proposal 3) are required to have different 1→0 transition timing to achieve the proposed time-division pre-charge. The length of an interval between two pre-charge timing control signals (particularly, an offset between 1→0 transition timing of separate pre-charge timing control signals) is inversely proportional to the magnitude of the peak current. That is, a larger interval between two pre-charge timing control signals can lead to better peak current reduction. In some embodiments of the present invention, the interval between two pre-charge timing control signals can be adjustable to achieve better control of the peak current reduction.

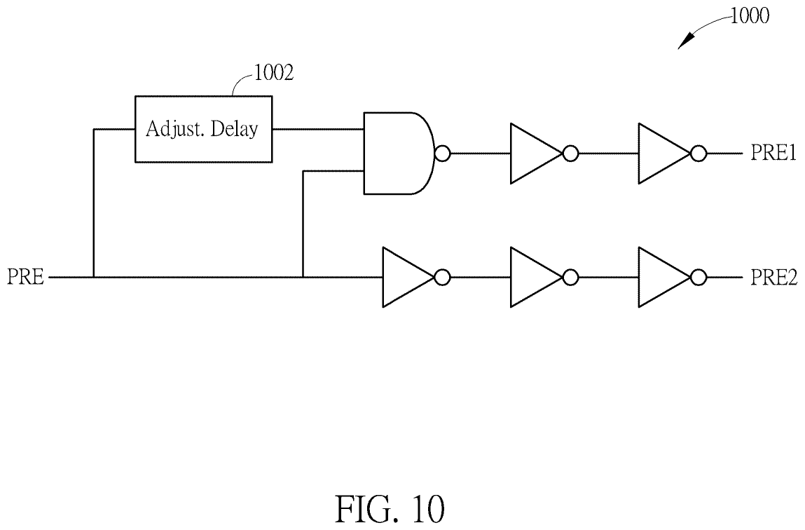

FIG. 10 is a diagram illustrating a pre-charge timing generator circuit according to an embodiment of the present invention. The pre-charge timing generator circuit 1000 may be a part of the timing controller circuit 108 shown in FIG. 1. The pre-charge timing generator circuit 1000 includes an adjustable delay circuit (labeled by “Adjust. Delay”) 1002. Two pre-charge timing control signals PRE1 and PRE2 output to the pre-charge circuit 110 are derived from the same reference pre-charge timing control signal PRE, where an interval between the pre-charge timing control signals PRE1 and PRE2 is adjusted by the adjustable delay circuit 1002. For example, the adjustable delay circuit 1002 operates in response to a user input. That is, the delay amount provided by the adjustable delay circuit 1200 is manually configured by the user.

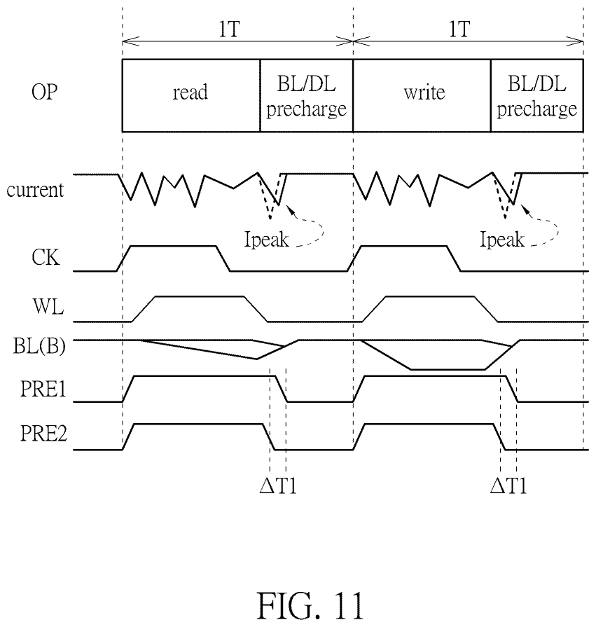

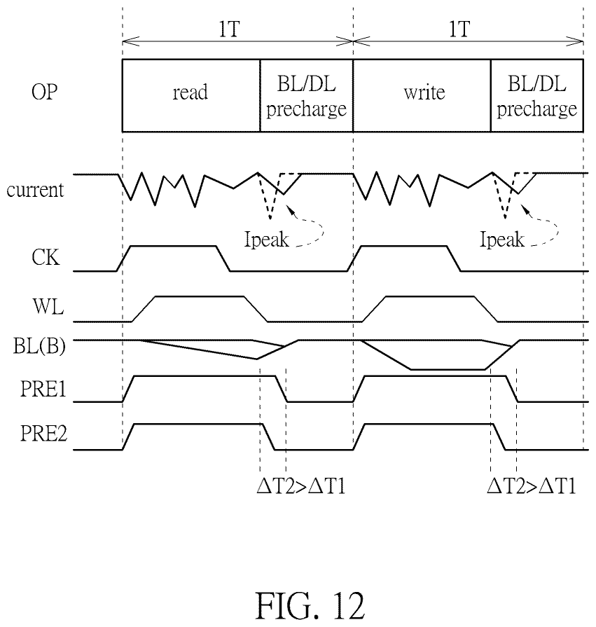

FIG. 11 is a diagram illustrating waveforms of a plurality of signals of the memory 100 using the pre-charge timing generator circuit 1000 with a first adjustable delay setting. FIG. 12 is a diagram illustrating waveforms of a plurality of signals of the memory 100 using the pre-charge timing generator circuit 1000 with a second adjustable delay setting. Since an interval ΔT2 between the pre-charge timing control signals PRE1 and PRE2 under the second adjustable delay setting is larger than an interval ΔT1 between the pre-charge timing control signals PRE1 and PRE2 under the first adjustable delay setting, the use of the second adjustable delay setting can lead to better peak current reduction.

Regarding the pre-charge timing generator circuit 1000 shown in FIG. 10, the adjustable interval between two pre-charge timing control signals may be manually configured by the user. However, this is for illustrative purposes only, and is not meant to be a limitation of the present invention. In some embodiments of the present invention, a self-adjustable interval between two pre-charge timing control signals (particularly, a self-adjustable offset between 1→0 transition timing of separate pre-charge timing control signals) may be adopted for automatic control of the peak current reduction.

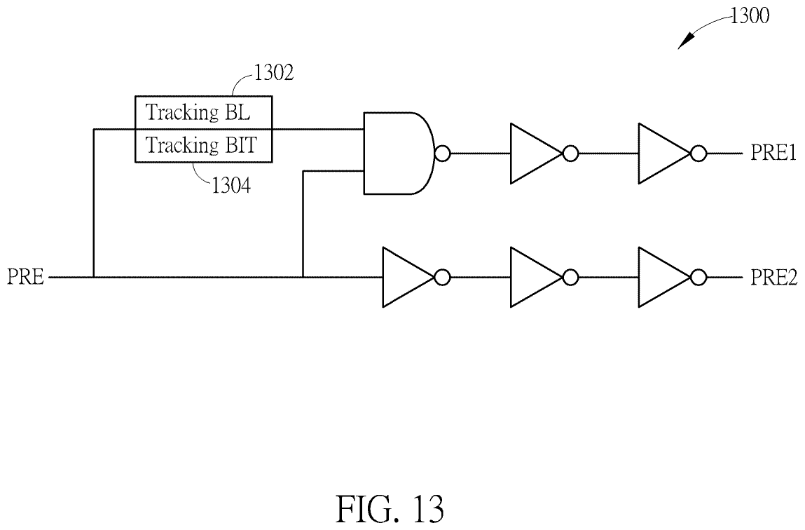

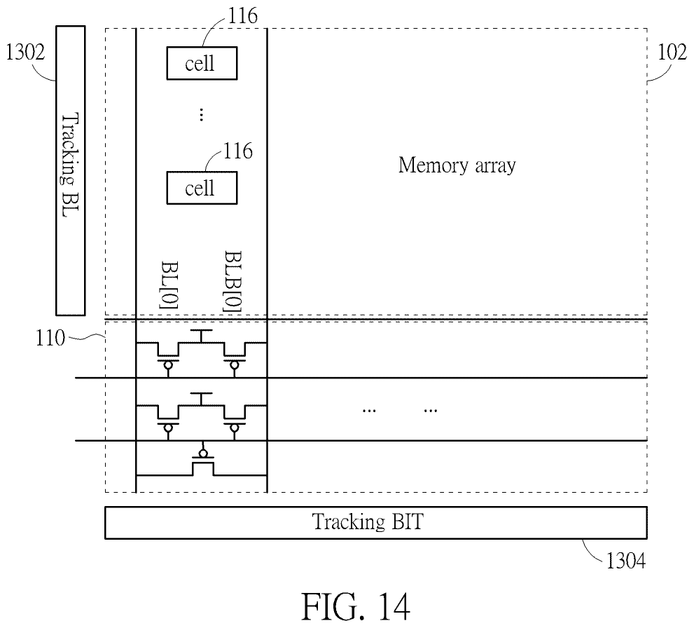

FIG. 13 is a diagram illustrating another pre-charge timing generator circuit according to an embodiment of the present invention. The pre-charge timing generator circuit 1300 may be a part of the timing controller circuit 108 shown in FIG. 1. The pre-charge timing generator circuit 1300 may include one or both of the tracking circuits (labeled by “Tracking BL” and “Tracking BIT”) 1302 and 1304. Two pre-charge timing control signals PRE1 and PRE2 output to the pre-charge circuit 110 are derived from the same reference pre-charge timing control signal PRE, where an interval between the pre-charge timing control signals PRE1 and PRE2 is adjusted by one or both of the tracking circuits 1302 and 1304. Each of the tracking circuits 1302 and 1304 is capable of adjusting the interval between the pre-charge timing control signals PRE1 and PRE2 by monitoring at least one parameter of the memory array 102. As shown in FIG. 14, the tracking circuit 1302 is arranged to monitor the bit-line length (i.e., the number of memory cells in a bit-line direction, or the word number), and the tracking circuit 1304 is arranged to monitor the number of bits (i.e., the number of memory cells in a word-line direction, or the word size). The peak current becomes worse at longer bit-line and/or larger bit-number. When an SRAM macro has longer bit-line and/or larger bit-number, the pre-charge timing generator circuit 1300 can automatically increase the interval between the pre-charge timing control signals PRE1 and PRE2 for better peak current reduction. When an SRAM macro has shorter bit-line and/or smaller bit-number, the pre-charge timing generator circuit 1300 can automatically decrease the interval between the pre-charge timing control signals PRE1 and PRE2 for speed penalty reduction.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A pre-charge system comprising:
a pre-charge circuit, arranged to perform time-division pre-charge upon a plurality of bit-line groups of a memory array according to a plurality of pre-charge timing control signals, wherein the memory array comprises a plurality of memory cells each coupled to one of the plurality of bit-line groups; and
a timing controller circuit, arranged to generate and output the plurality of pre-charge timing control signals to the pre-charge circuit.

2. The pre-charge system of claim 1, wherein each of the plurality of memory cells is a static random access memory (SRAM) cell.

3. The pre-charge system of claim 1, wherein the pre-charge circuit comprises:
a plurality of pre-charge sub-circuit groups, each comprising at least one pre-charge sub-circuit coupled to at least one of the plurality of bit-line groups and receiving one of the plurality of pre-charge timing control signals;
wherein the plurality of pre-charge timing control signals generated from the timing controller circuit enable the plurality of pre-charge sub-circuit groups sequentially.

4. The pre-charge system of claim 1, wherein the pre-charge circuit comprises:
a plurality of pre-charge sub-circuits, coupled to the plurality of bit-line groups, respectively, wherein each of the plurality of pre-charge sub-circuits receives the plurality of pre-charge timing control signals, and comprises:
an equalizer; and
a pre-charge device;
wherein the plurality of pre-charge timing control signals generated from the timing controller circuit enable the equalizer and the pre-charge device sequentially.

5. The pre-charge system of claim 1, wherein the pre-charge circuit comprises:
a plurality of pre-charge sub-circuits, coupled to the plurality of bit-line groups, respectively, wherein each of the plurality of pre-charge sub-circuits receives the plurality of pre-charge timing control signals, and comprises:
a first pre-charge device; and
a second pre-charge device, wherein pre-charge strength of the second pre-charge device is larger than pre-charge strength of the first pre-charge device;
wherein the plurality of pre-charge timing control signals generated from the timing controller circuit enable the first pre-charge device and the second pre-charge device sequentially.

6. The pre-charge system of claim 1, wherein the timing controller circuit comprises:
an adjustable delay circuit, arranged to adjust an interval between two of the plurality of pre-charge timing control signals.

7. The pre-charge system of claim 6, wherein the adjustable delay circuit operates in response to a user input.

8. The pre-charge system of claim 1, wherein the timing controller circuit comprises:
a tracking circuit, arranged to adjust an interval between two of the plurality of pre-charge timing control signals by monitoring at least one parameter of the memory array.

9. The pre-charge system of claim 8, wherein the at least one parameter of the memory array comprises a number of memory cells in a bit-line direction.

10. The pre-charge system of claim 8, wherein the at least one parameter of the memory array comprises a number of memory cells in a word-line direction.

11. A pre-charge method comprising:
generating a plurality of pre-charge timing control signals; and
performing time-division pre-charge upon a plurality of bit-line groups of a memory array according to the plurality of pre-charge timing control signals, wherein the memory array comprises a plurality of memory cells each coupled to one of the plurality of bit-line groups.

12. The pre-charge method of claim 11, wherein each of the plurality of memory cells is a static random access memory (SRAM) cell.

13. The pre-charge method of claim 11, wherein performing the time-division pre-charge upon the plurality of bit-line groups of the memory array according to the plurality of pre-charge timing control signals comprises:
providing the plurality of pre-charge timing control signals to a plurality of pre-charge sub-circuit groups, respectively, wherein each of plurality of pre-charge sub-circuit groups comprises at least one pre-charge sub-circuit coupled to at least one of the plurality of bit-line groups; and
in response to the plurality of pre-charge timing control signals, enabling the plurality of pre-charge sub-circuit groups sequentially.

14. The pre-charge method of claim 11, wherein performing the time-division pre-charge upon the plurality of bit-line groups of the memory array according to the plurality of pre-charge timing control signals comprises:
providing the plurality of pre-charge timing control signals to each of a plurality of pre-charge sub-circuits, wherein the plurality of pre-charge sub-circuits are coupled to the plurality of bit-line groups, respectively, and each of the plurality of pre-charge sub-circuits comprises:
an equalizer; and
a pre-charge device;
in response to the plurality of pre-charge timing control signals, enabling the equalizer and the pre-charge device sequentially.

15. The pre-charge method of claim 11, wherein performing the time-division pre-charge upon the plurality of bit-line groups of the memory array according to the plurality of pre-charge timing control signals comprises:
providing the plurality of pre-charge timing control signals to each of a plurality of pre-charge sub-circuits, wherein the plurality of pre-charge sub-circuits are coupled to the plurality of bit-line groups, respectively, and each of the plurality of pre-charge sub-circuits comprises:
a first pre-charge device; and
a second pre-charge device, wherein pre-charge strength of the second pre-charge device is larger than pre-charge strength of the first pre-charge device; and
in response to the plurality of pre-charge timing control signals, enabling the first pre-charge device and the second pre-charge device sequentially.

16. The pre-charge method of claim 11, wherein generating the plurality of pre-charge timing control signals comprises:
adjusting an interval between two of the plurality of pre-charge timing control signals by an adjustable delay.

17. The pre-charge method of claim 16, wherein the adjustable delay is configured in response to a user input.

18. The pre-charge method of claim 11, wherein generating the plurality of pre-charge timing control signals comprises:
adjusting an interval between two of the plurality of pre-charge timing control signals by monitoring at least one parameter of the memory array.

19. The pre-charge method of claim 18, wherein the at least one parameter of the memory array comprises a number of memory cells in a bit-line direction.

20. The pre-charge method of claim 18, wherein the at least one parameter of the memory array comprises a number of memory cells in a word-line direction.
